(19) United States
(12) Patent Application Publication
(10) Pub. No.: US 2008/0145533 A1
(43) Pub. Date: Jun. 19, 2008

(54) Substrate processing apparatus and substrate processing method

(75) Inventors: Koichi Honda, Toyama-shi (JP); Taketoshi Sato, Toyama-shi (JP)

Correspondence Address: BIRCH STEWART KOLASCH & BIRCH, PO BOX 747, FALLS CHURCH, VA, 22040-0747, US

(73) Assignee: HITACHI KOKUSAI ELECTRIC INC., Tokyo (JP)

(21) Appl. No.: 11/987,225

(22) Filed: Nov. 28, 2007

(30) Foreign Application Priority Data
Nov. 29, 2006 (JP) 2006-321676
Nov. 19, 2007 (JP) 2007-299277

(51) Int. Cl. C23C 16/02

(52) U.S. Cl. 427/248.1; 118/725

(57) ABSTRACT

Disclosed is a substrate processing apparatus, including a processing chamber to accommodate substrates therein; a heating unit to heat the substrates; a gas supply system to supply desired processing gas into the processing chamber; an exhaust system to exhaust an atmosphere in the processing chamber; and a control section, wherein the gas supply system includes: a plurality of gas nozzles to supply gas obtained by vaporizing one material which is liquid at room temperature and atmospheric pressure to different positions in the processing chamber; and a plurality of vaporizing units, which are respectively in communication with the plurality of gas nozzles, each to vaporize the material, and the control section controls amounts of vaporization of the material in the plurality of vaporizing units individually.

### BACKGROUND OF THE INVENTION

1. Field of the Invention

The present invention relates to a substrate processing apparatus and a substrate processing method, and more particularly, to a vertical ALD (Atomic Layer Deposition) apparatus using a film-forming liquid material and a substrate processing method using the vertical ALD apparatus.

2. Description of Related Art

In a conventional vertical ALD apparatus, as shown in FIG. 5, a single multihole nozzle 233a is used for one vaporizer 242 as a method for supplying a film-forming liquid material to a processing chamber 201.

According to this method, it is necessary to raise a temperature of the liquid material to secure sufficient amounts of vaporization depending upon characteristics of the liquid material, and this generates a residue due to pyrolysis of a liquid material at a vaporizing portion in the vaporizer 242, and this generates particles and causes clogging of the nozzle portion.

Furthermore, it is difficult to uniformly supply the vaporized gas which is controlled by the one vaporizer 242 from each of the holes of the single multihole nozzle 233a, and enhancement of processing uniformity between wafers is limited.

### SUMMARY OF THE INVENTION

It is, therefore, a main object of the present invention to provide a substrate processing apparatus and a substrate processing method capable of stably operating a vaporizing unit, and realizing excellent processing uniformity between substrates in substrate processing.

According to a first aspect of the present invention, there is provided a substrate processing apparatus, comprising:

a processing chamber to accommodate substrates therein; a heating unit to heat the substrates; a gas supply system to supply desired processing gas into the processing chamber; an exhaust system to exhaust an atmosphere in the processing chamber; and a control section, wherein the gas supply system includes: a plurality of gas nozzles to supply gas obtained by vaporizing one material which is liquid at room temperature and atmospheric pressure to different positions in the processing chamber; and a plurality of vaporizing units, which are respectively in communication with the plurality of gas nozzles, each to vaporize the material, and the control section controls amounts of vaporization of the material in the plurality of vaporizing units individually.

According to a second aspect of the present invention, there is provided a substrate processing method, comprising: providing a substrate processing apparatus, including a processing chamber to accommodate substrates therein; a heating unit to heat the substrates; a gas supply system to supply desired processing gas into the processing chamber; an exhaust system to exhaust an atmosphere in the processing chamber; and a control section, wherein the gas supply system includes: a plurality of gas nozzles to supply gas obtained by vaporizing one material which is liquid at room temperature and atmospheric pressure to different positions in the processing chamber; and a plurality of vaporizing units, which are respectively in communication with the plurality of gas nozzles, each to vaporize the material, and the control section controls amounts of vaporization of the material in the plurality of vaporizing units individually; and processing the substrates using the substrate processing apparatus by supplying vaporized gas of the material from the plurality of gas nozzles to the different positions in the processing chamber while controlling the amounts of vaporization of the material in the plurality of vaporizing units individually by the control section.

### BRIEF DESCRIPTION OF THE DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1 is a schematic perspective view for explaining a substrate processing apparatus according to preferred embodiments of the present invention;

FIG. 2 is a schematic vertical cross-sectional view for explaining a reaction furnace of the substrate processing apparatus according to the preferred embodiments of the present invention;

FIG. 3 is an enlarged sectional view taken along the line A-A in FIG. 2;

FIG. 4 is a block diagram for explaining a nozzle in a processing chamber and a supply system (vaporizer) of the substrate processing apparatus of the preferred embodiments of the present invention;

FIG. 5 is a block diagram for explaining a nozzle in a processing chamber and a supply system (vaporizer) of a conventional substrate processing apparatus;

FIG. 6 is a schematic diagram for explaining a configuration of a vaporizer used in the preferred embodiments of the present invention and a member attached to the vaporizer;

FIG. 7 is a schematic diagram showing vapor pressure curves of TEMAH and TEMAZ; and

FIG. 8 is a schematic diagram showing a vapor pressure curve of TDMAS.

### DESCRIPTION OF THE PREFERRED EMBODIMENTS

Next, preferred embodiments of the present invention will be explained.

In the preferred embodiments of the present invention, a plurality of (concretely, three) nozzles each having a single hole are disposed in a processing chamber instead of one multihole nozzle. A vaporizer is disposed for each of the plurality of nozzles, and vaporized gas supplied from each nozzle is independently controlled.

Since an amount of vaporization by one vaporizer can be reduced with respect to the total amount of vaporized gas supplied to the processing chamber by disposing a plurality of vaporizers, it is possible to use the vaporizer in a sufficiently wide temperature range in which a liquid material is not pyrolyzed and no residue remains. This prevents reduction in an operating rate of an apparatus due to particle or clogging caused by a residue.

Since amounts of vaporized gas supplied from the plurality of nozzles disposed in the processing chamber are independently controlled by vaporizers respectively provided especially for the nozzles, it is possible to enhance the uniformity of the substrate processing between wafers by adjusting supply of gas from the nozzles. Furthermore, since the apparatus includes the plurality of nozzles, and the supply of gas from each nozzle is reduced, the vaporized gas can be supplied to wafers under the condition that the vaporized gas is stabilized owing to the reduction in internal pressure in each nozzle. As a result, surface uniformity of a wafer can also be enhanced.

A vertical ALD apparatus of the preferred embodiment of the present invention includes a gas BOX having a unit capable of controlling a flow rate of gas for supplying a film-forming material, a low pressure processing chamber capable of vapor depositing the film-forming material on a wafer, and an exhaust system for the processing chamber.

The vertical ALD apparatus also includes a mass flow controller to supply the film-forming material, and a control system of an air valve. A plurality of film-forming materials which are liquid at room temperature and atmospheric pressure can be supplied to the processing chamber. The room temperature is in a range of 15 to 30° C., and preferably 20° C. The atmospheric pressure is 760 Torr.

As an example of the liquid material for film-forming, an amine-compound liquid material (such as TEMAH (tetrakis-ethylmethylamino Hafnium), TEMAZ (tetrakis-ethylmethylamino Zirconium), and TDMAT (tetrakis-dimethylamino Titanium)) can be used. This amine-compound liquid material is heated and can be supplied to the processing chamber as a film-forming material by vaporization and bubbling. Moreover, a plurality of nozzles each having a single hole are disposed in a reaction chamber. Such configuration makes it possible to suppress variation in vapor state due to rise in internal pressure, and to enhance the uniformity of film thickness between wafers by adjusting supplying positions of the vaporized gas to the processing chamber in order to keep the density of the vaporized gas uniform.

The amine-compound liquid material used in the preferred embodiments of the present invention has the property that the vapor pressure is low and the pyrolysis tend to occur at a low temperature. In order to carry the liquid material in a vapor state to surfaces of wafers without pyrolysis, it is necessary to prevent or suppress a change of state in a nozzle. This can be achieved by lowering the pressure in the nozzle. Because an internal pressure of a single-hole nozzle is lower than that of a multihole nozzle, using a single-hole nozzle is effective when the amine-compound liquid material is used.

If a single multihole nozzle is disposed in a reaction chamber, it is difficult to predict a supply rate of gas supplied from each hole because a flow rate of gas varies from hole to hole due to the pressure and the temperature in the reaction chamber and a supply rate of gas to the reaction chamber. Even if the supply rate of gas from each hole can be predicted, it is difficult to control a supply rate of gas because there is a need to adjust the supply rate of gas using several kinds of multihole nozzles which have different hole diameters from each other. On the other hand, such a disadvantage is avoided if a plurality of single-hole nozzles are disposed in the reaction chamber, and this is effective in controlling a supply rate of gas to the reaction chamber.

A plurality of film-forming materials including a liquid material are alternately supplied to the processing chamber, and during that time, it is possible to purge using inert gas. Under this condition, since the plurality of single-hole nozzles are used instead of one multihole nozzle to disperse the supply of the vaporized gas, an internal pressure of each of the nozzles can be reduced, and a liquid material is heated and can be supplied into the processing chamber as a film-forming material by vaporization and bubbling in a stable condition.

Next, preferred embodiments of the present invention will be explained in more detail with reference to the drawings.

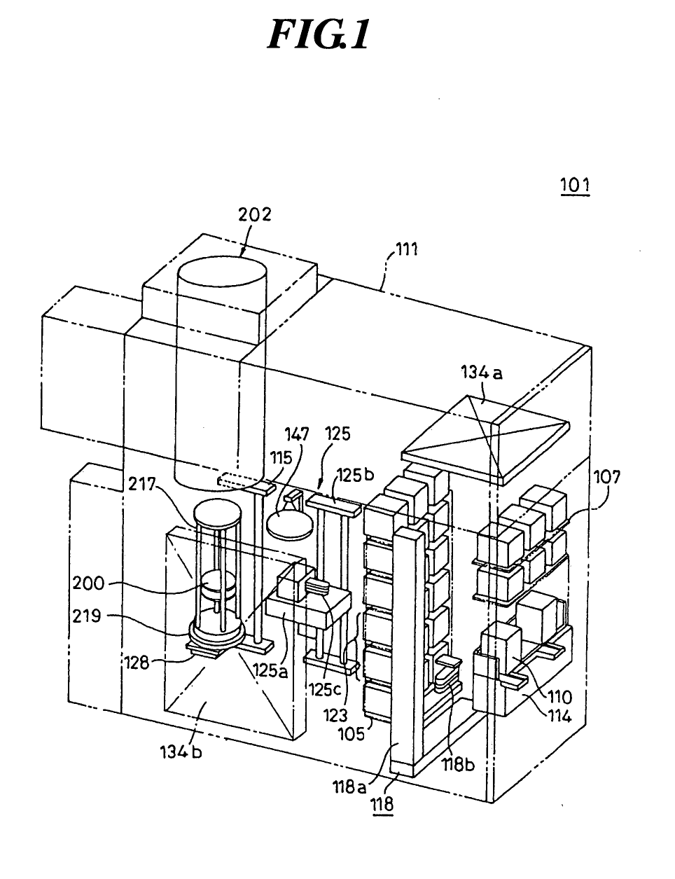

First, a substrate processing apparatus according to the preferred embodiment of the present invention will be explained with reference to FIG. 1. FIG. 1 is a schematic perspective view for explaining the substrate processing apparatus according to the preferred embodiment of the present invention.

As shown in FIG. 1, a processing apparatus 101 of the preferred embodiment uses cassettes 110 as wafer carriers which accommodate wafers (substrates) 200 made of silicon. The processing apparatus 101 includes a casing 111 having a front wall 111a. A front maintenance opening 103 as an opening is formed at a lower portion of the front wall 111a so that maintenance can be carried out. A front maintenance door 104 is provided for opening and closing the front maintenance opening 103. A cassette carry in/out opening (a substrate container carry in/out opening) 112 is formed at the maintenance door 104 so that an inside and an outside of the casing 111 are in communication through the cassette carry in/out opening 112. The cassette carry in/out opening 112 is opened and closed by a front shutter (substrate container carry in/out opening open/close mechanism) 113. A cassette stage (a substrate container delivery stage) 114 is disposed at the cassette carry in/out opening 112 inside the casing 111. The cassette 110 is transferred onto the cassette stage 114 by a transfer device (not shown) and carried out from the cassette stage 114.

The cassette 110 delivered by the transfer device is placed on the cassette stage 114 such that the wafers 200 in the cassette 110 are in their vertical attitudes and an opening of the cassette 110 for taking wafers in and out is directed upward. The cassette stage 114 is constituted such that it rotates the cassette 110 clockwisely in the vertical direction by 90° to rearward of the casing, the wafers 200 in the cassette 110 are in their horizontal attitudes, and the opening of the cassette 110 for taking wafers in and out is directed to rearward of the casing.

Cassette shelves (substrate container placing shelves) 105 are disposed substantially at a central portion in the casing 111 in its longitudinal direction, and the cassette shelves 105 store a plurality of cassettes 110 in a plurality of rows and a plurality of lines. The cassette shelves 105 are provided with transfer shelves 123 in which the cassettes 110 to be transferred by a wafer loading mechanism 125 are to be accommodated.

Auxiliary cassette shelves 107 are provided above the cassette stage 114 to subsidiarily store the cassettes 110.

A cassette transfer device (a substrate container transfer device) 118 is provided between the cassette stage 114 and the cassette shelves 105. The cassette transfer device 118 includes a cassette elevator (a substrate container elevator mechanism) 118a capable of vertically moving while holding the cassette 110, and a cassette transfer mechanism (a substrate container transfer mechanism) 118b as a transfer mechanism. The cassette transfer device 118 transfers the cassette 110 between the cassette stage 114, the cassette shelves 105 and the auxiliary cassette shelves 107 by a continuous motion of the cassette elevator 118a and the cassette transfer mechanism 118b.

A wafer loading mechanism (a substrate transfer mechanism) 125 is provided behind the cassette shelves 105. The wafer loading mechanism 125 includes a wafer loading device (a substrate loading device) 125a which can rotate or straightly move the wafer 200 in the horizontal direction, and a wafer loading device elevator (a substrate loading device elevator mechanism) 125b which vertically moves the wafer loading device 125a. The wafer loading device elevator 125b is provided on a right end of the pressure-proof casing 111. Tweezers (a substrate holding body) 125c of the wafer loading device 125a as a placing portion of the wafers 200 charges a boat (a substrate holding tool) 217 with wafers 200 and discharges the wafers 200 from the boat 217 by continuous motion of the wafer loading device elevator 125b and the wafer loading device 125a.

A processing furnace 202 is provided at a rear and upper portion in the casing 111. A lower end of the processing furnace 202 is opened and closed by a furnace opening shutter (a furnace opening open/close mechanism) 147.

A boat elevator (a substrate holding tool elevator mechanism) 115 is provided below the processing furnace 202 as an elevator mechanism for vertically moving the boat 217 to and from the processing furnace 202. A seal cap 219 as a lid is horizontally set up on an arm 128 as a connecting tool connected to an elevating stage of the boat elevator 115. The seal cap 219 vertically supports the boat 217, and can close a lower end of the processing furnace 202.

The boat 217 includes a plurality of holding members, and horizontally holds a plurality of wafers 200 (e.g., about 50 to 150 wafers) which are arranged in the vertical direction such that centers thereof are aligned with each other.

A clean unit 134a is provided above the cassette shelves 105. The clean unit 134a includes a dustproof filter and a supply fan for supplying clean air which is a purified atmosphere so that the clean air 133 flows into the casing 111.

A clean unit 134b comprising a supply fan for supplying clean air and a dustproof filter is provided on a left side of the casing 111, i.e. on the opposite side of the wafer loading device elevator 125b and the boat elevator 115. Clean air belched out from the clean unit 134b flows through the wafer loading device 125a and the boat 217, and then is sucked in by an exhaust device (not shown), and is exhausted outside the casing 111.

Next, an operation of the substrate processing apparatus according to the preferred embodiment of the present invention will be explained.

Before the cassette 110 is supplied to the cassette stage 114, the cassette carry in/out opening 112 is opened by the front shutter 113. Then, the cassette 110 is transferred in from the cassette carry in/out opening 112, and is placed on the cassette stage 114 such that the wafers 200 are in their vertical attitudes and the opening of the cassette 110 for taking wafers in and out is directed upward. Then, the cassette 110 is rotated clockwisely in the vertical direction by 90° to rearward of the casing so that the wafers 200 in the cassette 110 are in their horizontal attitudes, and the opening of the cassette 110 for taking wafers in and out is directed to rearward of the casing.

Next, the cassette 110 is automatically transferred onto a designated shelf position of the cassette shelves 105 or the auxiliary cassette shelves 107 by the cassette transfer device 118, and the cassette 110 is temporarily stored. After that, the cassette 110 is transferred onto the transfer shelves 123 from the cassette shelves 105 or the auxiliary cassette shelves 107 by the cassette transfer device 118, or directly transferred onto the transfer shelves 123.

When the cassette 110 is transferred onto the transfer shelves 123, the wafers 200 are picked up from the cassette 110 through the opening by the tweezers 125c of the wafer loading device 125a, and the boat 217 located behind a loading chamber 124 is charged with the wafers 200. The wafer loading device 125a which delivered the wafers 200 to the boat 217 returns to the cassette 110, and charges the boat 217 with the next wafers 200.

When the boat 217 is charged with a predetermined number of wafers 200, a lower end of the processing furnace 202 which was closed by the furnace opening shutter 147 is opened by the furnace opening shutter 147. Then, the boat 217 which holds a group of wafers 200 is loaded into the processing furnace 202 by moving the seal cap 219 upward by the boat elevator 115.

After the loading, the wafers 200 are subjected to arbitrary processing in the processing furnace 202.

After the processing, the wafers 200 and the cassette 110 are carried outside the casing 111 by reversing the above-described procedure.

Next, a substrate processing furnace of the substrate processing apparatus according to the preferred embodiment of the present invention will be explained.

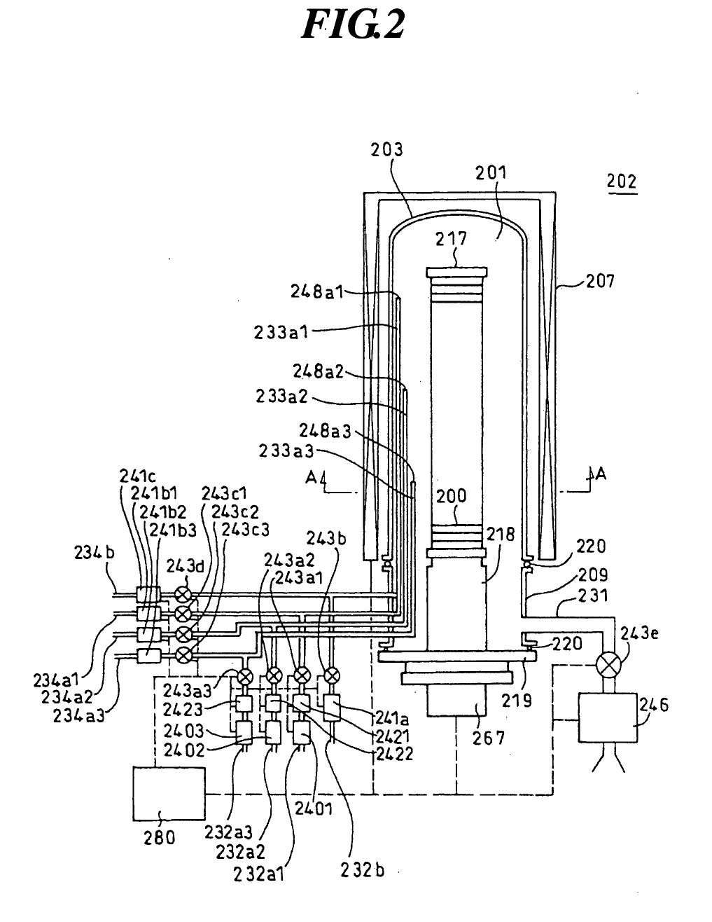

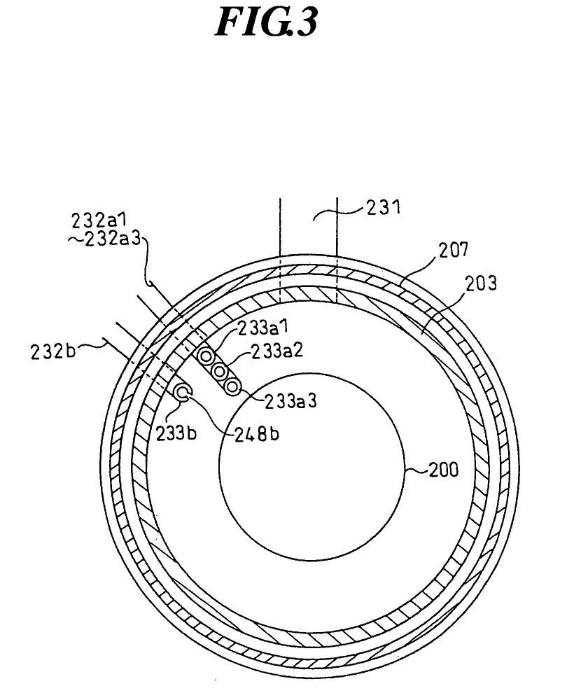

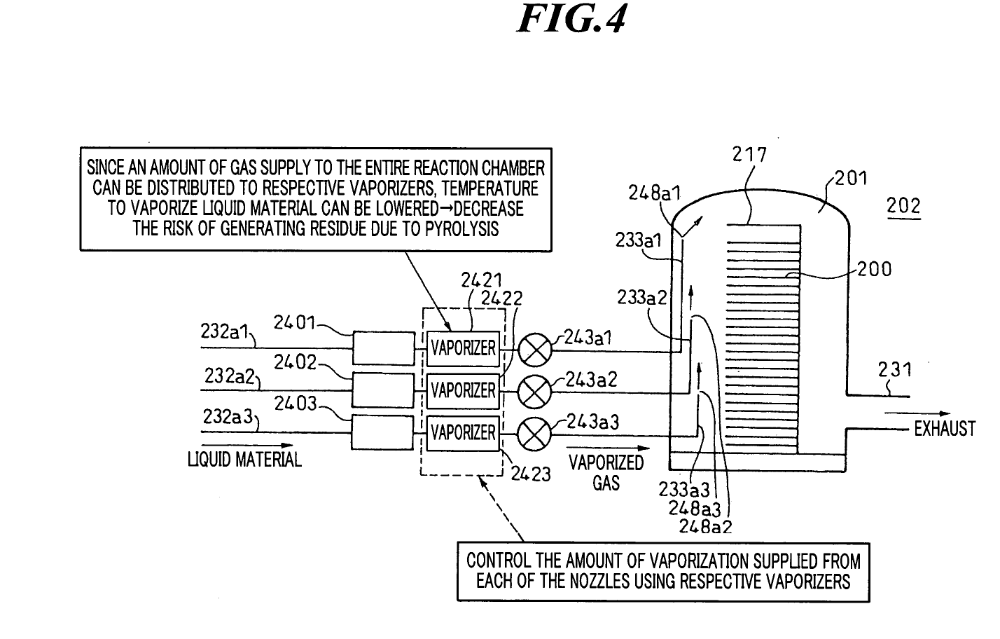

FIG. 2 is a schematic block diagram of a vertical substrate processing furnace which is preferably used in the preferred embodiment of the present invention, and is a vertical sectional view of a portion of the processing furnace 202. FIG. 3 is a schematic block diagram of a vertical substrate processing furnace which is preferably used in the embodiment, and is a sectional view of the portion of the processing furnace 202 taken along the line A-A in FIG. 2. FIG. 4 is a block diagram for explaining nozzles in a processing chamber and a supply system (vaporizer) of the substrate processing apparatus of the preferred embodiment of the invention.

A reaction tube 203 as a reaction container which processes the wafers 200 as substrates is provided inside a heater 207 which is a heating device (heating means). A manifold 209, which is made of stainless steal etc., is provided at a lower end of the reaction tube 203 through an O-ring 220 which is an air-tight member. A lower end opening of the manifold 209 is air-tightly closed by the seal cap 219 as a lid through an O-ring 220. The processing chamber 201 is formed by at least the reaction tube 203, the manifold 209 and the seal cap 219. The boat 217 which is the substrate holding member (substrate holding means) stands on the seal cap 219 through a boat support stage 218. The boat support stage 218 is a holding body which holds the boat. The boat 217 is inserted into the processing chamber 201. The plurality of wafers 200 which are to be subjected to batch process are stacked on the boat 217 in a horizontal attitude in multi-layers in the axial direction of the tube. The heater 207 heats the wafers 200 inserted into the processing chamber 201 to a predetermined temperature.

Two series of gas supply tubes (first series of gas supply tubes 232a1 to 232a3, a second series of gas supply tube 232b) as supply paths extend to the processing chamber 201 for supplying a plurality of kinds of (here, two kinds of) processing gases. Carrier gas supply tubes 234a1, 234a2 and 234a3 for supplying carrier gas respectively merge with the first series of gas supply tubes 232a1 to 232a3 through liquid mass flow controllers 2401 to 2403 which are flow rate control devices (flow rate control means), vaporizers 2421 to 2423, and valves 243a1 to 243a3 which are on/off valves in this order from upstream. The carrier gas supply tubes 234a1, 234a2, and 234a3 are respectively provided with mass flow controllers 241b1 to 241b3 which are flow rate control devices (flow rate control means) and valves 243c1 to 243c3 which are on/off valves in this order from upstream.

Tip ends of the gas supply tubes 232a1 to 232a3 are respectively provided with nozzles 233a1 to 233a3 in an arc space between the wafers 200 and an inner wall of the reaction tube 203 constituting the processing chamber 201 along the inner wall from a lower portion of the reaction tube 203 to a higher portion thereof in a stacking direction of the wafers 200. Tip ends of the nozzles 233a1 to 233a3 are respectively provided with gas supply holes 248a1 to 248a3 which are open to the processing chamber 201.

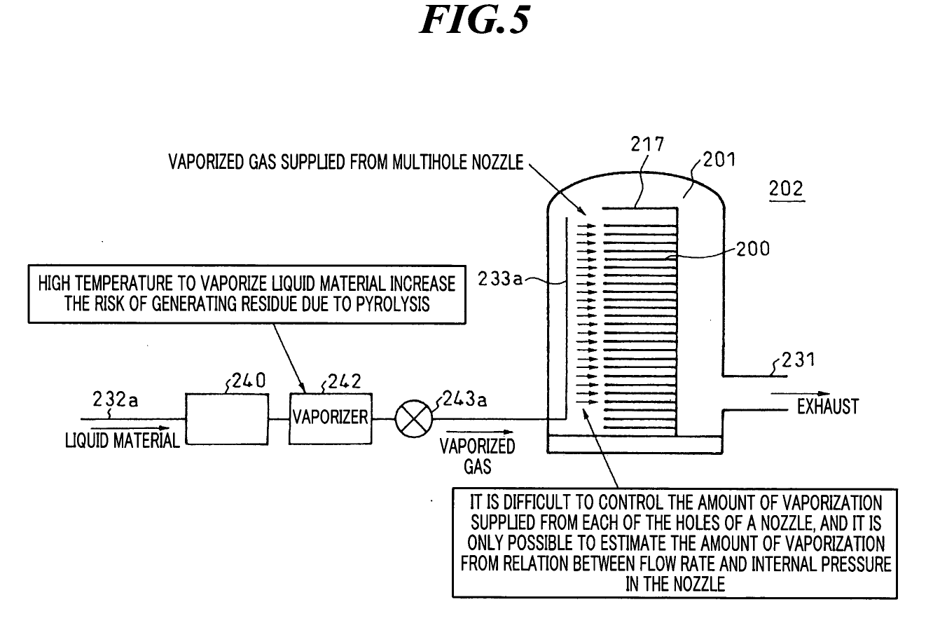

In the preferred embodiments of the present invention, the plurality of (three in the concrete example) single-hole nozzles 233a1 to 233a3 are used in the processing chamber 201 instead of the single multihole nozzle 233a as shown in FIG. 5.

A carrier gas supply tubes 234b which supplies carrier gas merges with a gas supply tube 232b through a mass flow controller 241a which is a flow rate control device (flow rate control means) and a valve 243b which is an on/off valve in this order from upstream. The carrier gas supply tubes 234b is provided with a mass flow controller 241c which is a flow rate control device (flow rate control means) and a valve 243d which is an on/off valve in this order from upstream. A tip end of the gas supply tube 232b is provided with a nozzle 233b in an arc space between the wafers 200 and the inner wall of the reaction tube 203 constituting the processing chamber 201 along the inner wall from a lower portion of the reaction tube 203 to a higher portion thereof in a stacking direction of the wafers 200. Gas supply holes 248b which are supply holes through which gas is supplied are formed in a side surface of the nozzle 233b. The gas supply holes 248b have the same opening areas from a lower portion to an upper portion of the nozzle 233b, and distances between adjacent openings are the same.

If a material supplied from the gas supply tubes 232a1 to 232a3 is liquid for example, the gas supply tubes 232a1 to 232a3 respectively merge with the carrier gas supply tubes 234a1, 234a2 and 234a3 through the liquid mass flow controllers 2401 to 2403, the vaporizers 2421 to 2423 and the valves 243a1 to 243a3, respectively, and reaction gas is supplied into the processing chamber 201 through the nozzles 233a1 to 233a3, respectively. When the material supplied from the gas supply tubes 232a1 to 232a3 is gas for example, the liquid mass flow controllers 2401 to 2403 are replaced by mass flow controllers for gas, and the vaporizers 2421 to 2423 are not necessary. The gas supply tube 232b merges with the carrier gas supply tubes 234b through the mass flow controller 241a and the valve 243b, and reaction gas is supplied to the processing chamber 201 through the nozzle 233b.

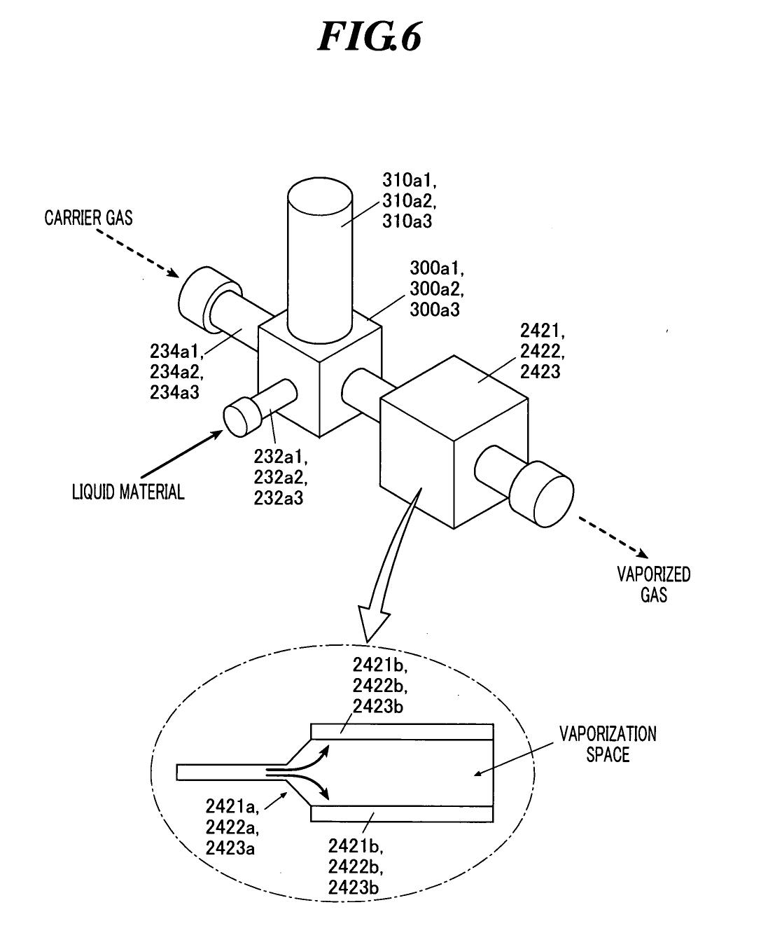

A structure in the vicinity of connections between the gas supply tubes 232a1 to 232a3 and the carrier gas supply tubes 234a1 to 234a3 may have a configuration shown in FIG. 6. As shown in FIG. 6, mixing sections 300a1 to 300a3 are respectively provided at the connections between the gas supply tubes 232a1 to 232a3 and the carrier gas supply tubes 234a1 to 234a3. The mixing sections 300a1 to 300a3 are respectively provided with flow rate control sections 310a1 to 310a3. The mixing sections 300a1 to 300a3 respectively mix liquid materials supplied from the gas supply tubes 232a1 to 232a3 and carrier gas supplied from the carrier gas supply tubes 234a1 to 234a3. The flow rates of the mixtures are controlled by the flow rate control sections 310a1 to 310a3, and then the mixtures are supplied to the vaporizers 2421 to 2423, respectively.

Flow paths 2421a to 2423a are respectively formed in the vaporizers 2421 to 2423. Intermediate sections of the flow paths 2421a to 2423a have a orifice structure. Heaters 2421b to 2423b are respectively provided in large diameter sections of the flow paths 2421a to 2423a. The mixtures supplied to the vaporizers 2421 to 2423 are respectively flowed through the flow paths 2421a to 2423a, the pressure is lowered at the orifice, and thereby the mixtures are respectively sprayed from small diameter sections towards the large diameter sections. The sprayed mixtures are respectively heated by the heaters 2421b to 2423b, flowed out from the vaporizers 2421 to 2423 as vaporized gas, and then supplied into the processing chamber 201 through the nozzles 233a1 to 233a3, respectively.

The processing chamber 201 is connected to a vacuum pump 246 which is an exhaust device (exhaust means) through a valve 243e by a gas exhaust pipe 231 which is an exhaust pipe from which gas is exhausted so that the processing chamber 201 is evacuated. The evacuation of the processing chamber 201 can be carried out or stopped by opening or closing the valve 243e. The valve 243e is an on/off valve which can adjust a pressure by adjusting the valve opening degree.

The boat 217 is provided at a central portion in the reaction tube 203. The plurality of wafers 200 are placed on the boat 217 at equal distances from one another in multi-layers. The boat 217 can come into and go out from the reaction tube 203 by a boat elevator mechanism (not shown). To enhance the processing uniformity, a boat rotating mechanism 267 is provided for rotating the boat 217. The boat 217 supported by the boat support stage 218 is rotated by driving the boat rotating mechanism 267.

A controller 280 which is a control section (control means) is connected to liquid mass flow controllers 2401, 2402 and 2403, mass flow controllers 241a, 241b1, 241b2, 241b3 and 241c, valves 243a1, 243a2, 243a3, 243b, 243c1, 243c2, 243c3, 243d and 243e, the heater 207, the vacuum pump 246, the boat rotating mechanism 267 and the boat elevator mechanism (not shown). The controller 280 controls the adjustment of flow rates of the liquid mass flow controllers 2401 to 2403 and the mass flow controllers 241a, 241b1, 241b2, 241b3 and 241c, controls opening and closing operations of the valves 243a1, 243a2, 243a3, 243b, 243c1, 243c2, 243c3 and 243d, controls opening and closing operation and adjustment of pressure of the valve 243e, controls the adjustment of temperature of the heater 207, controls actuation and stop of the vacuum pump 246, controls the adjustment of rotation speed of the boat rotating mechanism 267, and controls the vertical motion of the boat elevator mechanism.

In the preferred embodiments of the present invention, the vaporizers 2421 to 2423 are respectively disposed for the plurality of nozzles 233a1 to 233a3, and vaporized gas supplied from each of the nozzles 233a1 to 233a3 is independently controlled.

Since an amount of vaporization by one vaporizer can be reduced with respect to the total amount of vaporized gas supplied to the processing chamber 201 by disposing the plurality of vaporizers 2421 to 2423, it is possible to use the vaporizer in a sufficiently wide temperature range in which a liquid material is not pyrolyzed and no residue remains. This prevents reduction in an operating rate of an apparatus due to particle or clogging caused by a residue.

Since amounts of vaporized gas supplied from the plurality of nozzles 233a1 to 233a3 disposed in the processing chamber 201 are independently controlled by vaporizers respectively provided especially for the nozzles, it is possible to enhance the uniformity of the substrate processing between wafers 200 by adjusting supply of gas from the nozzles. Furthermore, since the apparatus includes the plurality of nozzles, and the supply of gas from each nozzle is reduced, the vaporized gas can be supplied to wafers 200 under the condition that the vaporized gas is stabilized owing to the reduction in internal pressure in each nozzle. As a result, surface uniformity of a wafer can also be enhanced.

As an example of a liquid material for film-forming, an amine-compound liquid material (such as TEMAH (tetrakis-ethylmethylamino Hafnium), TEMAZ (tetrakis-ethylmethylamino Zirconium), and TDMAT (tetrakis-dimethylamino Titanium)) can be used. This amine-compound liquid material is heated and can be supplied to the processing chamber 201 as a film-forming material by vaporization and bubbling. Moreover, a plurality of nozzles 233a1 to 233a3 each having a single hole are disposed in the processing chamber 201. Such configuration makes it possible to suppress variation in vapor state due to rise in internal pressure, and to enhance the uniformity of film thickness between wafers 200 by adjusting supplying positions of the vaporized gas to the processing chamber 201 in order to keep the density of the vaporized gas uniform.

The amine-compound liquid material used in the preferred embodiments of the present invention has the property that the vapor pressure is low and the pyrolysis tend to occur at a low temperature. In order to carry the liquid material in a vapor state to surfaces of wafers 200 without pyrolysis, it is necessary to prevent or suppress a change of state in a nozzle. This can be achieved by lowering the pressure in the nozzle. Because an internal pressure of a single-hole nozzle is lower than that of a multihole nozzle, using single-hole nozzles 233a1 to 233a3 is effective when the amine-compound liquid material is used.

If a single multihole nozzle is disposed in the processing chamber 201, it is difficult to predict a supply rate of gas supplied from each hole because a flow rate of gas varies from hole to hole due to the pressure and the temperature in the processing chamber 201 and a supply rate of gas to the processing chamber 201. Even if the supply rate of gas from each hole can be predicted, it is difficult to control a supply rate of gas because there is a need to adjust the supply rate of gas using several kinds of multihole nozzles which have different hole diameters from each other. On the other hand, such a disadvantage is avoided if a plurality of single-hole nozzles 233a1 to 233a3 are disposed in the processing chamber 201, and this is effective in controlling a supply rate of gas to the processing chamber 201.

A plurality of film-forming materials including a liquid material are alternately supplied to the processing chamber 201, and during that time, it is possible to purge using inert gas. Under this condition, since the plurality of single-hole nozzles 233a1 to 233a3 are used instead of a single multihole nozzle to disperse the supply of the vaporized gas, an internal pressure of each of the nozzles can be reduced, and a liquid material is heated and can be supplied into the processing chamber 201 as a film-forming material by vaporization and bubbling in stable condition.

Next, an example of film forming processing using an ALD method will be explained based on an example for forming a HfO₂ film using TEMAH and O₃ which is one of producing steps of a semiconductor device. The following example of the film forming processing is one example of the substrate processing methods.

According to the ALD (Atomic Layer Deposition) method which is one of CVD (Chemical Vapor Deposition) methods, at least two kinds of reaction gases as materials used for forming films are alternately supplied onto substrates under given film forming conditions (temperature, time, etc.), the reaction gas adheres onto the substrates by atom by atom, and films are formed utilizing surface reaction. At that time, the film thickness is controlled based on the number of cycles in which reaction gas is supplied (for example, if the film forming speed is 1 Å/cycle, in order to form a film of 20 Å, 20 cycles are carried out).

According to the ALD method, when HfO₂ films are to be formed for example, high quality films can be formed at a low temperature of 180 to 250° C. using TEMAH (Hf[NCH₃C₂H₅]₄, tetrakis methylethylamino hafnium) and O₃ (ozone).

First, the boat 217 is charged with the wafers 200, and the boat 217 is load into the processing chamber 201 as described above. After that, the following three steps are carried out sequentially.

(Step 1)

Flow the TEMAH through the gas supply tubes 232a1 to 232a3, and flow carrier gas (N₂) through the carrier gas supply tubes 234a. The valves 243a1 to 243a3 of the gas supply tubes 232a1 to 232a3, the valves 243c1 to 243c3 of the carrier gas supply tubes 234a1 to 234a3, and the valve 243e of the gas exhaust pipe 231 are opened. The carrier gas flows from the carrier gas supply tubes 234a1, 234a2 and 234a3, and flow rates thereof are adjusted by the mass flow controllers 241b1 to 241b3. The TEMAH flows from the gas supply tubes 232a1 to 232a3, flow rates thereof are adjusted by the liquid mass flow controllers 2401 to 2403. Then, the TEMAH is vaporized by the vaporizers 2421 to 2423, mixed with the carrier gas whose flow rate is adjusted, and the mixture is supplied into the processing chamber 201 from the gas supply holes 248a1 to 248a3 of the nozzles 233a1 to 233a3 while it is exhausted from the gas exhaust pipe 231. At that time, the valve 243e is appropriately adjusted, and the pressure in the processing chamber 201 is maintained at a predetermined pressure. A supply rate of TEMAH controlled by the liquid mass flow controller 240 is 0.01 to 0.1 g/min. The wafers 200 are exposed to the TEMAH gas for 30 to 180 seconds. At that time, the temperature of the heater 207 is set such that the wafer temperature becomes a predetermined value in a range of 180 to 250° C.

A surface reaction (chemical adsorption) with a surface portion such as an underlayer film on the wafer 200 occurs by supplying the TEMAH into the processing chamber 201.

(Step 2)

Next, the valves 243a1 to 243a3 of the gas supply tubes 232a1 to 232a3 are closed, and the supply of TEMAH is stopped. At that time, the valve 243e of the gas exhaust pipe 231 is kept open, the gas is exhausted from the processing chamber 201 to 20 Pa or lower by the vacuum pump 246, and remaining TEMAH gas is exhausted from the processing chamber 201. If inert gas such as N₂ or the like is supplied into the processing chamber 201, the effect for eliminating the remaining TEMAH is further enhanced.

(Step 3)

Next, flow O₃ through the gas supply tube 232b and flow carrier gas (N₂) through the carrier gas supply tubes 234b. The valve 243b of the gas supply tube 232b and the valve 243d of the carrier gas supply tubes 234b are opened. The carrier gas flows from the carrier gas supply tubes 234b, and the flow rate thereof is adjusted by the mass flow controller 241b. The O₃ flows from the gas supply tube 232b, the flow rate thereof is adjusted by the mass flow controller, the O₃ is mixed with the carrier gas whose flow rate is adjusted, and the mixture is supplied into the processing chamber 201 from the gas supply holes 248b of the nozzle 233b while it is exhausted from the gas exhaust pipe 231. At that time, the valve 243e is appropriately adjusted and the pressure in the processing chamber 201 is adjusted to a predetermined pressure. The wafers 200 are exposed to O₃ for 10 to 120 seconds. The heater 207 is set such that the temperature of the wafers at that time becomes a predetermined temperature within a range of 180 to 250° C. as in the supply operation of TEMAH gas in step 1. By supplying O₃, the O₃ and the TEMAH which is chemically adsorbed on the surfaces of the wafers 200 reacts with each other, and an HfO₂ film is formed on each of the wafers 200.

After the films are formed, the valve 243b of the gas supply tube 232b and the fourth valve 243d of the carrier gas supply tubes 234b are closed, the processing chamber 201 is evacuated by the vacuum pump 246, and remaining O₃ gas after the film formation is eliminated. If inert gas such as N₂ is supplied into the reaction tube 203, the effect for eliminating the remaining O₃ gas is enhanced.

The steps 1 to 3 are defined as one cycle, and if this cycle is repeated a plurality of times, HfO₂ films having predetermined film thickness can be formed on the wafers 200.

According to the preferred embodiments of the present invention, because a plurality of vaporizers 2421 to 2423 are disposed, an amount of vaporization by one vaporizer with respect to the total amount of vaporized gas supplied to the processing chamber 201 can be reduced as compared to the case where one vaporizer is disposed. Therefore, it is possible to lower the temperature of the vaporizers 2421 to 2423, and thereby a temperature of the liquid material in the vaporizers 2421 to 2423 can be lower than a pyrolysis temperature. This prevents the generation of a residue due to pyrolysis of the liquid material, and the generation of particles and clogging of the nozzle portion due to the residue. As a result, it is possible to stably operate the vaporizers 2421 to 2423.

As one comparative example of the present embodiments, if one vaporizer is disposed, the temperature of the liquid material to be vaporized may be raised when increasing an amount of vaporization of the liquid material. In this case, the liquid material autolyzes owing to heat, and thereby a residue is generated in the vaporizer. If the residue adheres to an inside of the vaporizer, temperature of a vaporization space is lowered, and a sufficient amount of vaporization cannot be obtained. On the other hand, in the present embodiments, it is possible to avoid the situation that a residue is generated and an amount of vaporization is insufficient because the temperature of the liquid material to be vaporized can be lower than the pyrolysis temperature.

As a method for increasing an amount of vaporization of a liquid material in the above-described comparative example, it is also possible to extend the time of vaporized gas supply instead of raising the temperature to vaporize the liquid material. But this method could cause a decrease in throughput. Therefore, it is more effective to raise the temperature of the liquid material as a method for increasing an amount of vaporization of the liquid material, as compared with extending supply time of the vaporized gas.

As an another comparative example of the present embodiments, increasing an amount of supply of a liquid material to a vaporizer is conceivable, this, however, is not desirable because the vaporization of the liquid material is insufficient. As a still another comparative example for increasing an amount of vaporization of a liquid material, a vaporization space in a vaporizer is expanded (i.e., the vaporizer grows in size), which is not desirable because a temperature of the vaporization space should be higher than the temperature of the liquid material to be vaporized. For example, if a temperature of an inside of the vaporization space is a predetermined temperature (for example, which is higher than the temperature of the liquid material to be vaporized and lower than the pyrolysis temperature), a temperature of an outside of the vaporization space should be higher than the pyrolysis temperature. Therefore, growing the vaporizer in size is not desirable because the pyrolysis of the liquid material might occur.

In view of the above-described comparative examples, the preferred embodiments of the present invention are effective when using a liquid material that is easier to pyrolytically decompose as the temperature rises, and more effective particularly when using a liquid material which is to be vaporized at a temperature close to the pyrolysis temperature (i.e., difference between the temperature to vaporize the liquid material and the pyrolysis temperature is small).

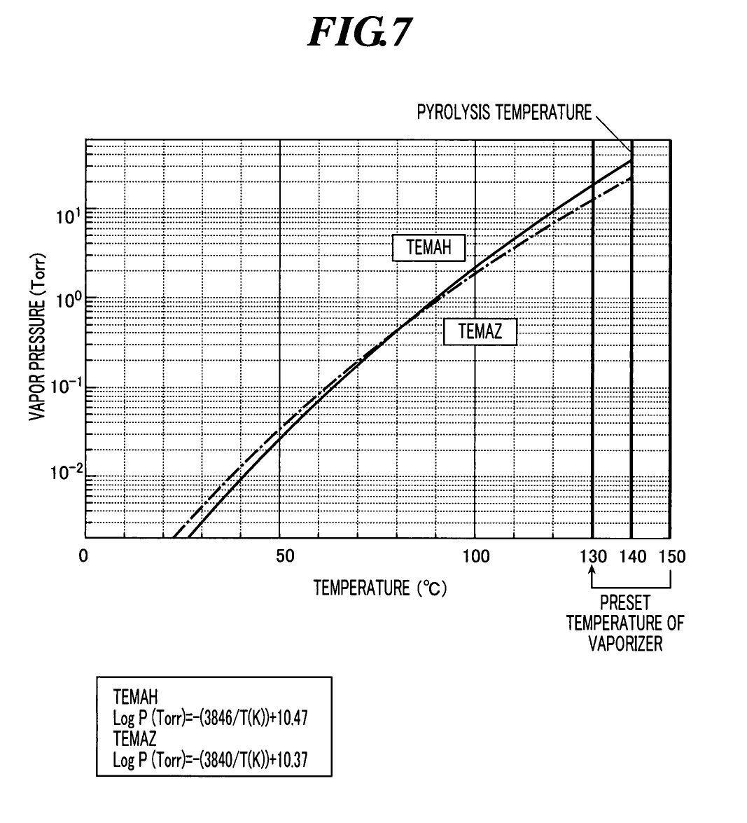

Here, effectiveness of the embodiments when using TEMAH and TEMAZ as a specific example of the liquid material will be explained. FIG. 7 is a schematic diagram showing vapor pressure curves of TEMAH and TEMAZ. The pyrolysis temperature of TEMAH (solid line) and TEMAZ (dashed-dotted line) is about 140° C., and is basically independent of pressure. A preset temperature of a vaporizer when vaporizing TEMAH and TEMAZ is about 150° C. The preset temperature of a vaporizer is a preset temperature in a vaporization space (see an enlarged view in FIG. 6) when increasing an amount of vaporization of a liquid material by a single vaporizer.

If a liquid material is vaporized by a single vaporizer, there is a possibility that the liquid material is pyrolytically decomposed because the preset temperature of the vaporizer is higher than the pyrolysis temperature of the liquid material. On the other hand, if the liquid material is vaporized by the plurality of vaporizers 2421 to 2423 as in the preferred embodiments, it is possible to lower the preset temperature of each of the vaporizers from about 150° C. to about 130° C. because an amount of vaporization by one of the plurality of vaporizers is reduced. Thus, the preset temperature of each of the vaporizers 2421 to 2423 can be lower than the pyrolysis temperature of the liquid material. As a result, this prevents the generation of a residue due to pyrolysis of the liquid material, and the vaporizers 2421 to 2423 can be operated stably.

When a pressure in the processing chamber 201 is in a range of 50 to 100 Pa (about 0.4 to 0.8 Torr) (for example, when processing the wafers 200), a pressure of a gas outlet (downstream side) of a vaporizer is in a range of 10 to 20 Torr. Under this condition, if the preset temperature of each of the vaporizers 2421 to 2423 can be lowered to about 130° C., TEMAH and TEMAZ can be kept in a vapor state as shown in FIG. 7, and it is possible to avoid reliquefaction of the liquid material.

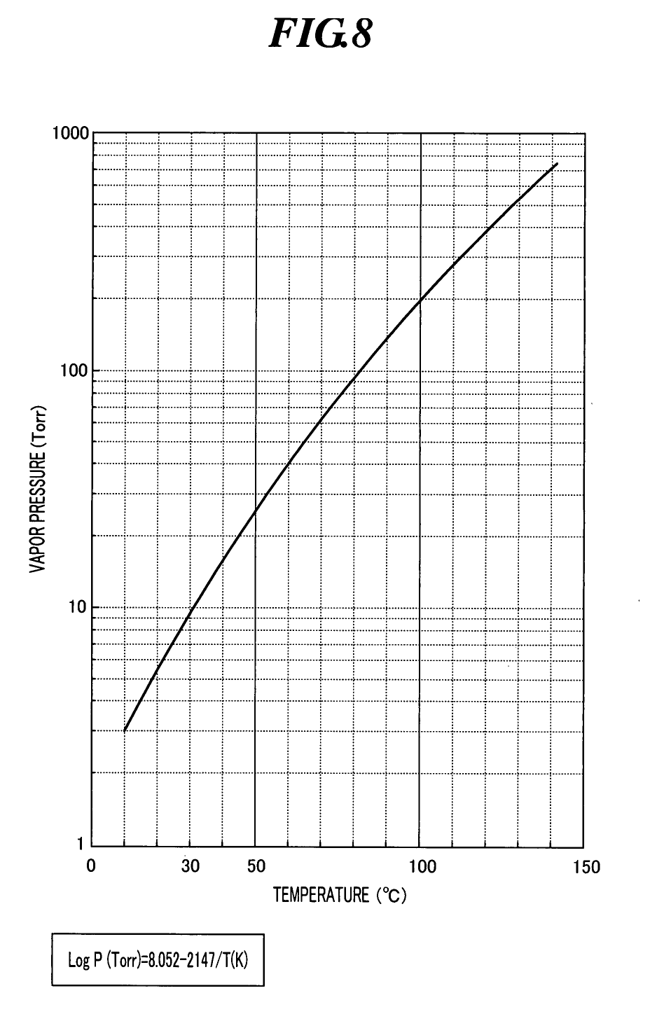

Next, a comparative example of the above-described TEMAH and TEMAZ where TDMAS (Tris (dimethylamino) silane) is used will be explained. FIG. 8 is a schematic diagram showing a vapor pressure curve of TDMAS. A pyrolysis temperature of the TDMAS is about 500° C., whereas a temperature to vaporize the liquid material is about 30° C. (if a pressure of a downstream side of a vaporizer is 10 Torr). Under this condition, because the pyrolysis temperature of the liquid material is very different from the temperature to vaporize the liquid material, and the temperature to vaporize the liquid material is lower than the pyrolysis temperature, it seems unlikely that a residue is generated. Therefore, the present embodiments are effective when using a liquid material that difference between the temperature to vaporize the liquid material and the pyrolysis temperature is small. Preferably, the temperature to vaporize the liquid material is lower than the pyrolysis temperature thereof, and a difference between the temperature to vaporize the liquid material and the pyrolysis temperature is within 50° C. under the condition that a pressure at an outlet of a vaporizer is 20 Torr or lower.

According to the preferred embodiments of the present invention, because supplies of the vaporized gas by the vaporizers 2421 to 2423 are controlled individually, it is possible to easily adjust the total amount of the vaporized gas supplied to the processing chamber 201, and to realize processing uniformity between wafers 200. Because the plurality of single-hole nozzles 233a1 to 233a3 are disposed instead of a single multihole nozzle, the supply of the vaporized gas to the processing chamber 201 can be dispersed (that is, the supply of the vaporized gas by one nozzle can be reduced), and thereby an internal pressure of one nozzle can be reduced. Therefore, the vaporized gas can be supplied to the wafers 200 in the processing chamber 201 in a vapor state in a stable condition. As a result, it is possible to realize excellent processing uniformity between wafers 200.

According to a first aspect of the preferred embodiments of the present invention, there is provided a substrate processing apparatus, comprising: a processing chamber to accommodate substrates therein; a heating unit to heat the substrates; a gas supply system to supply desired processing gas into the processing chamber; an exhaust system to exhaust an atmosphere in the processing chamber; and a control section, wherein the gas supply system includes: a plurality of gas nozzles to supply gas obtained by vaporizing one material which is liquid at room temperature and atmospheric pressure to different positions in the processing chamber; and a plurality of vaporizing units, which are respectively in communication with the plurality of gas nozzles, each to vaporize the material, and the control section controls amounts of vaporization of the material in the plurality of vaporizing units individually.

According to the first aspect of the preferred embodiments of the present invention, there is provided a substrate processing apparatus capable of stably operating a vaporizing unit, and realizing excellent processing uniformity between substrates in substrate processing.

Preferably, a temperature to vaporize the material in each of the plurality of the vaporizing units is lower than a pyrolysis temperature of the material, and a difference between the temperature to vaporize the material in each of the vaporizing units and the pyrolysis temperature is within 50° C. under a condition that a pressure at an outlet of each of the vaporizing units is 20 Torr or lower.

Preferably, the material is TEMAH.

Preferably, the material is TEMAZ.

Preferably, each of the nozzles is provided with a single hole which is open to the processing chamber.

According to a second aspect of the preferred embodiments of the present invention, there is provided a substrate processing method, comprising:

providing a substrate processing apparatus, including a processing chamber to accommodate substrates therein; a heating unit to heat the substrates; a gas supply system to supply desired processing gas into the processing chamber; an exhaust system to exhaust an atmosphere in the processing chamber; and a control section, wherein the gas supply system includes: a plurality of gas nozzles to supply gas obtained by vaporizing one material which is liquid at room temperature and atmospheric pressure to different positions in the processing chamber; and a plurality of vaporizing units, which are respectively in communication with the plurality of gas nozzles, each to vaporize the material, and the control section controls amounts of vaporization of the material in the plurality of vaporizing units individually; and

processing the substrates using the substrate processing apparatus by supplying vaporized gas of the material from the plurality of gas nozzles to the different positions in the processing chamber while controlling the amounts of vaporization of the material in the plurality of vaporizing units individually by the control section.

According to the second aspect of the preferred embodiments of the present invention, there is provided a substrate processing method capable of stably operating a vaporizing unit, and realizing excellent processing uniformity between substrates in substrate processing.

The entire disclosures of Japanese Patent Application No. 2006-321676 filed on Nov. 29, 2006 and Japanese Patent Application No. 2007-299277 filed on Nov. 19, 2007 each including description, claims, drawings, and abstract are incorporated herein by reference in their entireties.

Although various exemplary embodiments have been shown and described, the invention is not limited to the embodiments shown. Therefore, the scope of the invention is intended to be limited solely by the scope of the claims that follow.

What is claimed is:

1. A substrate processing apparatus, comprising:
a processing chamber to accommodate substrates therein;
a heating unit to heat the substrates;
a gas supply system to supply desired processing gas into the processing chamber;
an exhaust system to exhaust an atmosphere in the processing chamber; and
a control section, wherein
the gas supply system includes:
a plurality of gas nozzles to supply gas obtained by vaporizing one material which is liquid at room temperature and atmospheric pressure to different positions in the processing chamber; and
a plurality of vaporizing units, which are respectively in communication with the plurality of gas nozzles, each to vaporize the material, and
the control section controls amounts of vaporization of the material in the plurality of vaporizing units individually.

2. The substrate processing apparatus according to claim 1, wherein a temperature to vaporize the material in each of the plurality of the vaporizing units is lower than a pyrolysis temperature of the material, and a difference between the temperature to vaporize the material in each of the vaporizing units and the pyrolysis temperature is within 50° C. under a condition that a pressure at an outlet of each of the vaporizing units is 20 Torr or lower.

3. The substrate processing apparatus according to claim 2, wherein the material is TEMAH.

4. The substrate processing apparatus according to claim 2, wherein the material is TEMAZ.

5. The substrate processing apparatus according to claim 1, wherein each of the nozzles is provided with a single hole which is open to the processing chamber.

6. A substrate processing method, comprising:
providing a substrate processing apparatus, including a processing chamber to accommodate substrates therein; a heating unit to heat the substrates; a gas supply system to supply desired processing gas into the processing chamber; an exhaust system to exhaust an atmosphere in the processing chamber; and a control section, wherein the gas supply system includes: a plurality of gas nozzles to supply gas obtained by vaporizing one material which is liquid at room temperature and atmospheric pressure to different positions in the processing chamber; and a plurality of vaporizing units, which are respectively in communication with the plurality of gas nozzles, each to vaporize the material, and the control section controls amounts of vaporization of the material in the plurality of vaporizing units individually; and
processing the substrates using the substrate processing apparatus by supplying vaporized gas of the material from the plurality of gas nozzles to the different positions in the processing chamber while controlling the amounts of vaporization of the material in the plurality of vaporizing units individually by the control section.
